(19) United States
(12) Patent Application Publication
(10) Pub. No.: US 2005/0232438 A1
(43) Pub. Date: Oct. 20, 2005

(54) Event-driven content playback system for vehicles

(76) Inventors: Otman A. Basir, Waterloo (CA); Jean-Pierre Bhavnani, Waterdown (CA); David Bullock, Waterloo (CA)

Correspondence Address: CARLSON, GASKEY & OLDS, P.C., 400 WEST MAPLE ROAD, SUITE 350, BIRMINGHAM, MI, 48009, US

(21) Appl. No.: 10/824,190

(22) Filed: Apr. 14, 2004

(51) Int. Cl. H04B 1/00; H03G 3/00

(52) U.S. Cl. 381/86; 381/61

(57) ABSTRACT

This invention describes a system that plays back content based on user-configurable in-vehicle function triggers, and manual user triggers. The invention may be used for a variety of applications such as vehicle personalization and customization, vehicle event-acknowledgement, and entertainment. In one example, the control unit ties to the remote keyless entry (RKE) system and uses the RKE wireless buttons as playback triggers for the content. In-vehicle subsystems such as warning and information signals or other systems with manual triggers like the RKE system may also be tied to the vehicle unit to trigger content playback. Content delivery scenarios provide secure and robust transmission from an original source to the vehicle unit. The vehicle unit stores the content in an on-board storage. Content loading and operation of the system is configured using a computer or handheld device.

### BACKGROUND OF THE INVENTION

This invention relates to an event-driven content playback system for vehicles, where user-selected media clips are associated with vehicle functions and are played based upon the activation of the associated vehicle functions.

Vehicle customization has long been a hobby for many automobile enthusiasts. Modifications to vehicles such as tinted windows, additional lighting, large-capacity stereos, hydraulic suspensions, decals etc. have all been used as means of enthusiasts to entertain themselves and be unique. Similarly, the proliferation of customized ring tones has exploded amongst cell phone users. This invention combines the two ideas allowing the user to customize and improve the sound the vehicle makes when a given event occurs. This includes replacing the traditional horn sound outside the vehicle when pressing buttons on a key fob to replacing a low gas warning tone on the inside of the vehicle. In the previous examples, audio and/or visual/optical content could be used to replace the traditional tones.

The prior art includes RKE and vehicle security systems that replace the existing manufacturer's RKE with added functionality such as a siren capable of pre-programmed tones. Traditional systems only make use of the vehicle's horn and occasionally the vehicle's head and tail lights. These systems are limited by the horn and siren's capabilities and are not capable of receiving and employing new content (audio or optical). The proposed invention can work with any existing RKE or vehicle security system, or any other event generating system such as the in-vehicle monitoring system that sends warning signals for low gas, low oil pressure etc.

### SUMMARY OF THE INVENTION

This invention describes a system that plays back content based on user-configurable in-vehicle subsystem triggers, and manual user triggers. The invention may be used for a variety of applications such as vehicle personalization and customization, vehicle event-acknowledgement, and entertainment. In one embodiment, the control unit ties to the remote keyless entry (RKE) and/or vehicle security system and uses the RKE wireless buttons as playback triggers for the content. In-vehicle subsystems such as warning and information signals or other systems with manual triggers like the RKE system may also be tied to the vehicle unit to trigger content playback. Included in the invention are content delivery scenarios that allow for secure and robust transmission from an original source to the vehicle unit. The vehicle unit stores the content in an on-board storage. Content loading and operation of the system is configured using a computer or handheld device software.

The invention comprises a vehicle unit, which has interfaces to receive and store the content, interfaces to receive playback event triggers, control circuitry, storage, software and lastly playback hardware if not already provided by the vehicle.

### BRIEF DESCRIPTION OF THE DRAWINGS

Other advantages of the present invention can be understood by reference to the following detailed description when considered in connection with the accompanying drawings wherein:

FIG. 1 is a schematic of an event-driven playback system according to the present invention.

FIG. 2 illustrates a first system and method for distributing media to the event-driven playback system of FIG. 1.

FIG. 3 illustrates a second system and method for distributing media to the event-driven playback system of FIG. 1.

FIG. 4 illustrates a third system and method for distributing media to the event-driven playback system of FIG. 1.

FIG. 5 illustrates a fourth system and method for distributing media to the event-driven playback system of FIG. 1.

FIG. 6 illustrates one possible user interface for providing content to the event-driven playback system of FIG. 1.

### DETAILED DESCRIPTION OF THE PREFERRED EMBODIMENTS

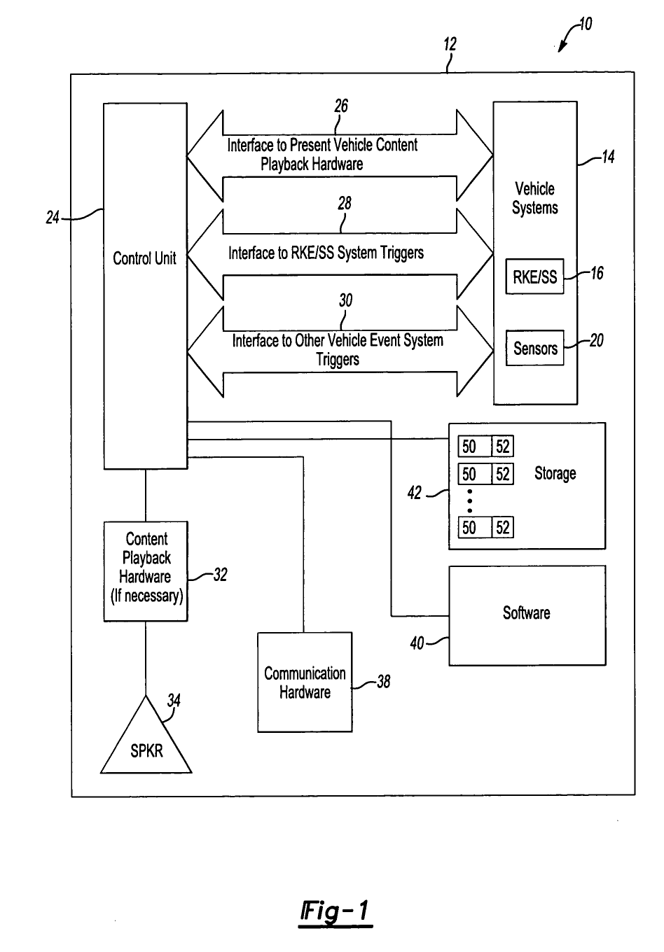

An event-driven content playback system 10 according to the present invention is shown schematically in FIG. 1 installed in a vehicle 12 having vehicle systems 14, including an RKE/vehicle security system 16 and other vehicle sensors 20. The RKE/vehicle security system 16 could be an RKE system, vehicle security system or both and may include sensors and actuators for door lock, primary door unlock, all doors unlock, trunk release, panic and remote start, for example. The sensors 20 include any other vehicle sensors 20 whose output may or could generate a warning or indication to a person. The sensors 20 may include low gas warning, low oil pressure warning, low windshield washer fluid warning, seatbelt(s) not connected warning, engine problem warning, brake problem warning, airbag problem warning, anti-lock-brake system problem warning, low battery warning, high temperature warning, door ajar warning, trunk ajar warning, hood ajar warning, etc.

The system 10 includes a control unit 24 with an interface to present vehicle content playback hardware 26, an interface to RKE/SS system triggers 28 and an interface to the other vehicle event system triggers 30. The system 10 optionally includes content playback hardware 32, such as a decoder, amplifier, etc and a transducer, such as a speaker 34. Content playback hardware and software may be included for content-specific playback, such as, but not limited to an amplifier and external speaker for audio, or additional lighting for optical content. The control unit 24 is connected to communication hardware 38, such as wired and wireless communication hardware, such as RF, BlueTooth, IEEE 802.11, USB port, removable media reader, etc. The communication hardware 38 is preferably a BlueTooth transceiver.

The system 10 further includes software 40, for storing the programs, algorithms, and other information needed to operate the present invention. The system 20 also includes on-board storage 42, such as a hard drive, RAM or other memory or digital storage, for storing content 50 and associating them with vehicle functions 52. In the example described here, the content 50 are audio files, such as MP3s, WAV, or other complex sound clips, which may be compressed.

The control unit 24 is configured to play back the stored content 50 in the event of a set of predefined vehicle functions 52. Upon detecting the occurrence of a vehicle function 52, the control unit 24 references the assigned content 50 for the vehicle function 52 and plays back this content 50 through its own hardware, or content playback hardware 32.

As indicated, the present invention could be used in conjunction with may different vehicle functions. However, for purposes of illustration, the present invention will be described with respect to an RKE system. Operation of the present invention with other vehicle functions should be apparent in light of this description.

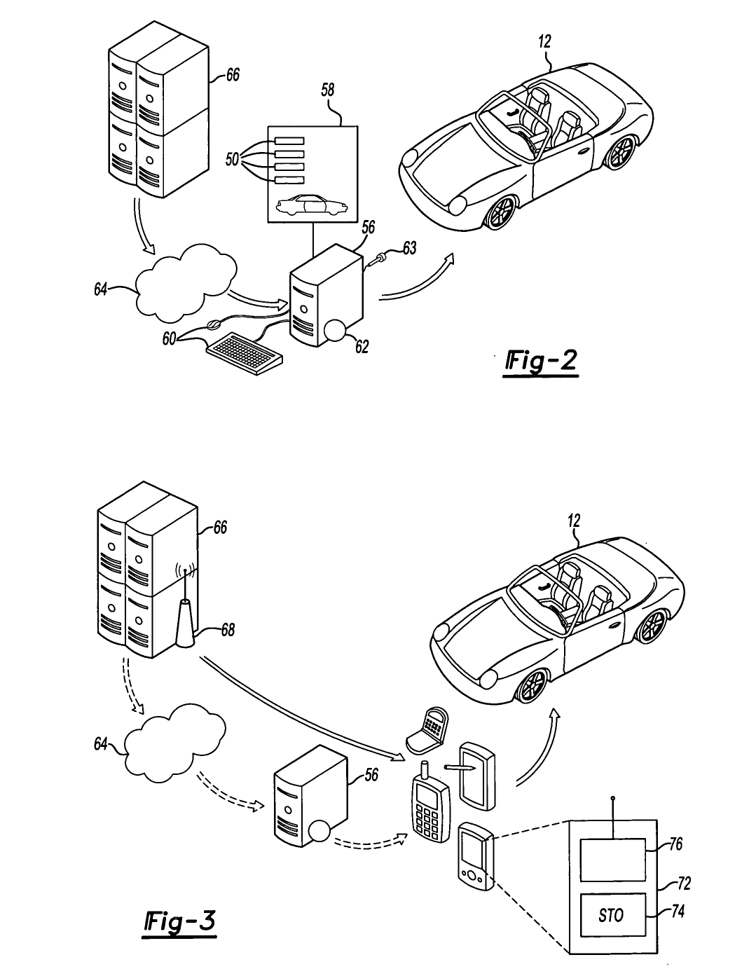

One example for distributing the content 50 to the vehicle 12 is shown in FIG. 2. A provided software application runs on a computer 56 to permit a user to select content and assign it to various vehicle functions. The computer 56 includes a display 58, mouse and keyboard or other input devices 60, a wireless transceiver 62 and a microphone 63. The computer program on the computer 56 allows the user to select from available content 50 and assign selected content 50 to the vehicle function event-triggers to which the vehicle unit has been tied. The available event triggers depends on the RKE system employed and what other systems may have been tied to the vehicle unit. For example, the user can choose a music clip or a ring-tone to play when he or she triggers the unlock key on his/her RKE fob. Another example, the user can choose a music clip or ring tone to play when he/she triggers the panic key on the RKE fob. Each event may be assigned unique content 50 if desired. The software provides a user-friendly interface to associate content 50 to a trigger function and an option to preview the content 50 prior to assigning it to a given vehicle function. Content 50 may take on a multitude of forms including but not limited to audio clips, video clips, ring tones, maps, documents etc. and may have come from any original source.

The selected content 50 is then sent to the vehicle 12 (in one of a variety of ways) and stored in storage 42 (FIG. 1). In order to playback content upon the occurrences of these events, the control unit 24 must have received and stored the content in the on-board storage 42.

Four differing transmission scenarios are presented as possible means of transferring content to the vehicle unit. In all cases, upon reception of the content data, the vehicle unit's software stores the content and which event the content is tied to in the on-board storage. The following transmission paths are disclosed as part of the invention

FIG. 2 illustrates the transfer of the content 50 from a user computer 56 to the vehicle unit wirelessly via transceiver 62. There are no intermediary steps; however, the personal computer must be within the functional range of the wireless hardware. The content is stored on the computer 56 from the original source 66 through any means available. The original source 66 may be servers on an internet web site. In this embodiment, both the computer 56 and vehicle 12 unit must be equipped with wireless communication hardware. In the preferred embodiment, the wireless protocol uses Bluetooth technology.

A software application on the computer 56 is used to establish a connection via a wide area network 64 (such as the internet). Upon connecting, the control unit 24 transmits its status, including but not limited to currently stored content 50 and available vehicle functions 52. Once the user has selected and assigned content to the vehicle functions 52, the content 50 and assignment with the vehicle functions 52 is wirelessly transmitted to the control unit 24 via the software application. Additionally, the computer 56 includes a microphone 63, such that recorded audio received over the microphone 63 is stored as content 50 on the computer 56 for transmission to the vehicle 12 and association with vehicle functions 52.

The second path is illustrated in FIG. 3 and includes a wireless handheld device 72, such as a PDA, cell phone, or email device, including on-board storage and a wireless transceiver 76. In this system and method, the content 50 is selected and the user associates vehicle functions 52 with each content 50. The content 50 is then transmitted from the original source 66 via a wireless transmitting system 68 to a wireless-enabled handheld device and then to the control unit 24. The wireless transmitting system 68 may be wireless internet access, or a wireless email or phone network. The selected content from the original source 66 is stored on the handheld device 72 through any available means. This handheld device 72 must contain enough storage 74 to hold the transferred content 50 and have the ability to re-transmit the content to the control unit 24. The wireless capabilities of the handheld device 72 and the control unit 24 must be compatible. In the preferred embodiment, the wireless protocol uses Bluetooth technology, which would be in addition to the wireless transceiver in the handheld device used to communicate with the system 68.

A software application on the handheld device 72 is used to establish a connection. Upon connecting, the control unit 24 transmits its status, including but not limited to currently stored content 50 and available vehicle functions 52. Once the user has selected and assigned content 50 to the vehicle functions 52, the content 50 and assignment is wirelessly transmitted to the control unit 24 via the software application.

Intermediate steps from the original source 66 to the handheld device 72 are also possible. The content 50 may be transferred by any means from the original source 66, to the computer 56, or other intermediate device, and then transferred again, by any means available to the handheld device 72. Alternatively, the content may be transmitted to the handheld device 72 via a wired connection, such as USB, Firewire, etc. The content 50 is then transferred wirelessly to the control unit 24 as described above.

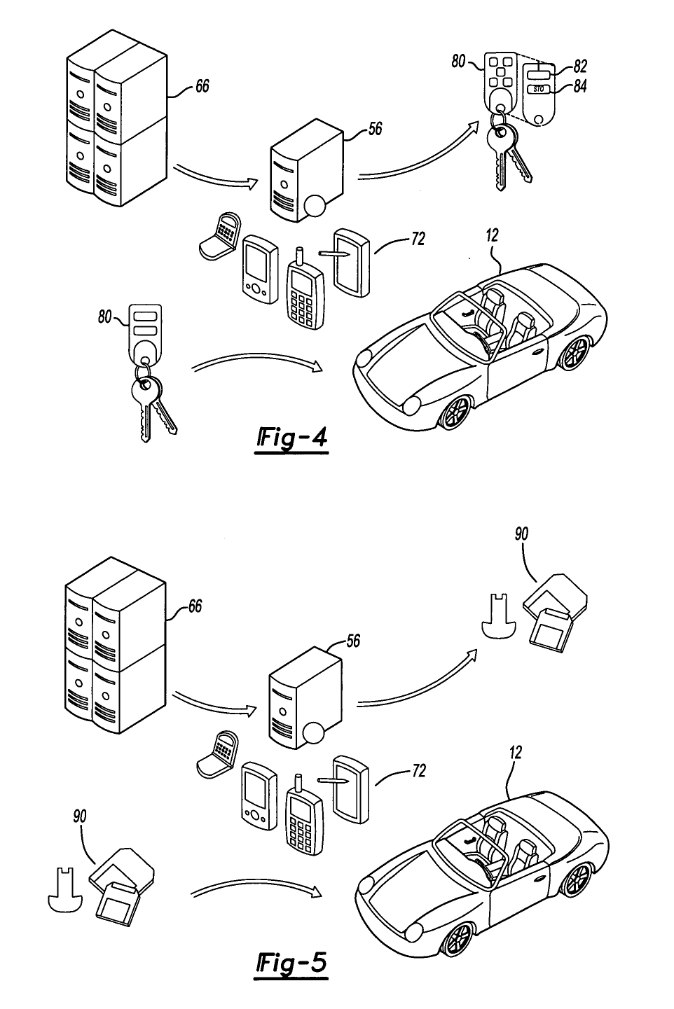

A third path is illustrated in FIG. 4, and includes an additional device, the wireless key fob 80. This device contains a wireless transceiver 82, storage 84, and any necessary control circuitry and software (not shown). This wireless key fob 80 can be programmed to perform the functions of the pre-existing remote keyless entry system as well as content delivery functions for the current invention. Configuration of the wireless key fob 80 (for both remote keyless entry and content delivery) is done using the computer 56 or handheld device 72 running a software application and may be performed over wire or wirelessly.

The software application allows the user to program the specific RKE key fob functions that replace the existing vehicle's remote keyless entry fob 80. Additionally, the software allows the user to configure automated content transfer or manual content transfer and lastly, the software allows the user to select and assign the content 50 to the available vehicle functions 52.

The content 50 is initially transferred from the original source 66 to a personal computer 56 or handheld device 72 and then to the wireless key fob 80, and lastly to the control unit 24. Once the user has selected and assigned the desired content to the available events, the wireless key fob 80 stores the content 50 in on-board storage 84 via a wired or wireless connection to the computer 56 or handheld device 72. When the wireless key fob 80 is in range of the control unit 24, a wireless link is established and the wireless key fob 80 can transfer the content 50 to the control unit 24. This transmission can be configured in the software application to occur automatically when in range, or manually by the user using a button on the wireless key fob 80. An indicator may be provided on the wireless key fob 80 to notify the user of the system status, which may include but is not limited to the following states: connection established, on going transmission, error has occurred and transmission complete.

FIG. 5 illustrates the transmission of content 50 from any original source 66, to the vehicle 12 via a portable portable storage media 90. A software application on a computer 56 or handheld device 72 allows the user to select the available stored content 50 and assign it to the vehicle functions 52 available to the control unit 24. In this embodiment, the system 10 can be configured to automatically initiate a data transfer upon connection or allow the user to press a synchronize button on the control unit 24. The software then stores the content 50 and assigned trigger data to the portable storage media 90. The portable storage media 90 is then physically connected to the control unit 24 where to transmission to the control unit 24 occurs automatically or manually depending on its configuration. Optionally, the control unit 24 can make use of the portable storage media 90 rather than, or in addition to, using on-board storage 42 (FIG. 1). In this case, when an event is detected by the control unit 24 for which content is to be played, the control unit 24 accesses the portable storage media 90 to retrieve and playback the content 50. An indicator may be provided on the control unit 24 to notify the user of the system status and may include but is not limited to the following: a connection is established, transmission is on going, an error has occurred and transmission has completed. The physical connection of the portable media storage 90 can be directly to the control unit 24 or to a provided port located in the vehicle.

In the wireless transmission paths disclosed above, the devices communicating with the control unit 24 must establish a wireless connection. There is the possibility that more than one control units 24 is in the proximity of the connecting device. Therefore, there exists the need to perform a discovery and authorization process. Software on the connecting device, will enumerate the control units 24 that are in the vicinity and automatically establish a connection to the control unit 24 that was linked during the initial configuration of the system. During the initial configuration, the connecting device(s) are “married” to the control unit 24(s) to which they will be connecting using an identification/authorization scheme. The connecting devices may be “married” to multiple control units 24; in this case, if both control units 24 are in the vicinity of the connecting device, the software will allow the user to select which vehicle they wish to connect to. The control unit 24 will only allow connections from “married” connecting devices to ensure unauthorized access to the control unit 24 is prevented. This applies to the wireless communication methodologies utilizing a computer 56, handheld devices 72 and wireless key fob 80.

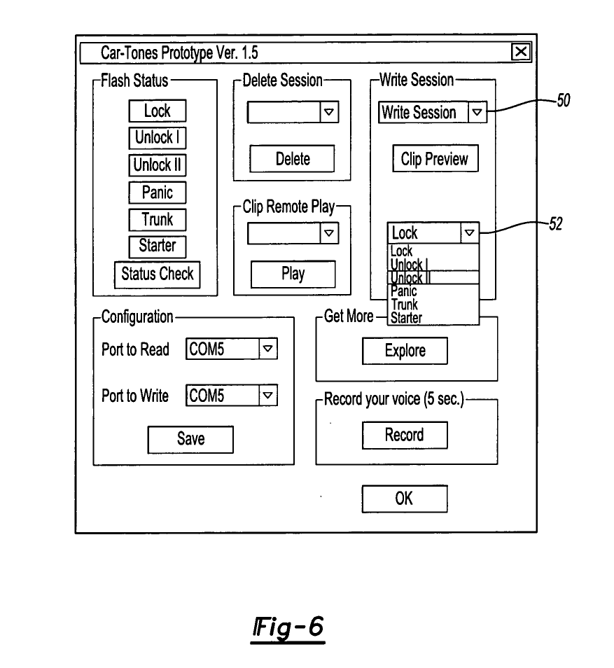

FIG. 6 illustrates one possible user interface that could be displayed on the display 58 of the computer 56 (FIG. 2) and on the display of the handheld device 72 (FIG. 3). In this user interface, the user can associate the content 50 with the vehicle functions 52, preview the content 50, record new content 50 (using microphone 63 of FIG. 2) and otherwise configure the system 10.

In accordance with the provisions of the patent statutes and jurisprudence, exemplary configurations described above are considered to represent a preferred embodiment of the invention. However, it should be noted that the invention can be practiced otherwise than as specifically illustrated and described without departing from its spirit or scope.

1. A user-customizable vehicle notification system comprising:
storage for storing at least one audio file on a vehicle and associating each at least one audio file with activation of a vehicle function; and
an audio player for selectively playing the at least one audio file upon activation of the associated vehicle function.

2. The system of claim 1 further including at least one speaker for receiving an audio signal from the audio player.

3. The system of claim 1 further including a wireless receiver for receiving the at least one audio file and storing the at least one audio file in the storage.

4. The system of claim 1 further including a user interface for associating the at least one audio file with the vehicle function.

5. The system of claim 4 wherein the user interface further provides for the selection of the at least one audio file over a wide area network.

6. The system of claim 5 wherein the user interface is provided on a user's computer.

7. The system of claim 1 further including a handheld device for temporarily storing the at least one audio file and for sending the at least one audio file to the storage.

8. The system of claim 7 further including a wireless receiver for receiving the at least one audio file and storing the at least one audio file in the storage, and wherein the handheld device includes a wireless transmitter for sending the at least one audio file to the wireless receiver.

9. The system of claim 8 further including a user interface for associating the at least one audio file with the vehicle function.

10. The system of claim 9 wherein the user interface further provides for the selection of the at least one audio file over a wide area network.

11. The system of claim 10 wherein the user interface is provided on a user's computer.

12. The system of claim 11 wherein the at least one audio file is a compressed audio file.

13. The system of claim 12 wherein the at least one audio file includes a plurality of different audio files, each associated with a different one of the plurality of vehicle functions.

14. The system of claim 1 further including a transducer for recording audio to a first audio file of the at least one audio file, the first audio file stored in the storage and associated with a first vehicle function, the audio player selectively playing the first audio file upon activation of the first vehicle function.

15. The system of claim 1 wherein the associated vehicle function is the locking a remote keyless entry system.

16. The system of claim 1 wherein the associated vehicle function is an alarm on a security system.

17. A method for playing an audio file including the steps of:
a) selecting an audio file;
b) storing the selected audio file on a vehicle;
c) associating the selected audio file with a vehicle function; and
d) playing the selected audio file based upon activation of the vehicle function.

18. The method of claim 17 wherein step a) further includes the step of:
e) accessing the audio file from a computer over a wide area network.

19. The method of claim 18 further including the step of:
f) sending the selected audio file wirelessly to the vehicle after said step a).

20. The method of claim 19 wherein said step f) further includes the step of sending the selected audio file wirelessly from the computer to the vehicle.

21. The method of claim 19 wherein said step f) further includes the steps of:
g) sending the selected audio file wirelessly to an intermediate storage device; and
h) sending the selected audio file from the intermediate storage device to the vehicle.

22. The method of claim 21 wherein the selected audio file is transmitted wirelessly in said step h).

23. The method of claim 17 further including the steps of:
g) sending the selected audio file to an intermediate storage device; and
h) sending the selected audio file from the intermediate storage device to the vehicle.

24. The method of claim 23 wherein the selected audio file is transmitted wirelessly in said step g).

25. The method of claim 23 wherein the intermediate storage device is a key fob.
